(19) United States
(12) Patent Application Publication
(10) Pub. No.: US 2011/0091722 A1
(43) Pub. Date: Apr. 21, 2011

(54) METHOD FOR PRODUCING SILICON-CONTAINING CERAMIC STRUCTURES

(76) Inventors: Martin Koehne, Asperg (DE); Viacheslav Bekker, Karlsruhe (DE); Juergen Oberle, Sindelfingen (DE)

(21) Appl. No.: 12/736,460

(22) PCT Filed: Mar. 31, 2009
(86) PCT No.: PCT/EP2009/053807

§ 371 Date: Dec. 28, 2010

(30) Foreign Application Priority Data
Apr. 8, 2008 (DE) 102008001063.4

(51) Int. Cl. C04B 35/622; C04B 35/00; H01B 1/12; G03F 7/20; B82Y 40/00

(52) U.S. Cl. 428/336; 501/154; 252/500; 430/325; 977/734; 977/742

(57) ABSTRACT

In a method for producing silicon-containing ceramic structures, structures of a ceramic precursor polymer are provided on the surface of a substrate, the ceramic precursor polymer being selected from the group including polysiloxanes, polycarbosilanes, polysilazanes and/or polyureasilazanes, and the ceramic precursor structures being ceramicized on the substrate. In the method, the structures of the ceramic precursor polymer have a height of ≦20 μm and a width perpendicular to their longitudinal axis of ≦500 μm.

### BACKGROUND OF THE INVENTION

1. Field of the Invention

The present invention relates to a method for producing silicon-containing ceramic structures, as well as to sensors that include such silicon-containing ceramic structures.

2. Description of Related Art

Silicon-based microelectromechanical structures (MEMS) are not usable, or are usable only to a limited degree, in environments that have high temperatures or an aggressive atmosphere. Such silicon-based systems may be protected from the environment to a certain extent by encapsulation. This is achieved by a sealing enclosure having appropriate thermal insulation. However, the encapsulation influences the resolution of the sensors to a high degree, both absolutely and in terms of time. Heretofore, the resulting inertia and imprecision of the microelectromechanical sensors have prevented wide distribution of MEMS in applications in a harsh environment. Furthermore, the need of encapsulation prevents the utilization of certain sensor principles. An example would be gas sensors having direct media contact.

Sensors based on ceramic structures are better suited for use in adverse environments. Such ceramics may be based, for example, on silicon carbide (SiC) or silicon nitride (Si₃N₄). However, when producing ceramics it must be kept in mind that deformations occur while a greenbody is being ceramicized to finished ceramics. These are caused by volume differences between the greenbody and the finished ceramics. In the usual dimensions for microelectromechanical sensors, however, the shrinkage may result in the component no longer being functional.

Published international patent application document WO 01/10791 discloses polymer-ceramic composite materials having nearly zero shrinkage compared to the original shape after final partial pyrolysis, and having thermal expansion behavior (preferably in an application range of 400° C. or lower) comparable to that of metallic construction materials, in particular gray cast iron or steel. The polymer-ceramic composite materials may be used, for example, instead of or in contact with steel or gray cast iron as temperature-resistant molded parts, primarily in machine construction without postprocessing following the original molding process. Preferred examples of suitable polymers are organosilicon polymers, in particular easily machined polysiloxane resins, but also polysilanes, polycarbosilanes, polysilazanes, polyborosilazanes or mixtures of these. However, that publication relates to components on a macroscopic scale. For example, molded parts having larger dimensions are named, such as a minimum outside diameter of more than 20 mm or more than 50 mm.

As a result, there is still a need for an improved production method for ceramic microstructures containing silicon.

### BRIEF SUMMARY OF THE INVENTION

The present invention provides a method for producing silicon-containing ceramic structures, wherein structures of a ceramic precursor polymer are provided on the surface of a substrate, the ceramic precursor polymer being selected from the group including polysiloxanes, polycarbosilanes, polysilazanes and/or polyureasilazanes and the ceramic precursor structures being ceramicized on the substrate. In the method according to the present invention, the structures of the ceramic precursor polymer have a height of ≦20 μm and a width perpendicular to their longitudinal axis of ≦500 μm.

Silicon-containing ceramic structures in the context of the present invention may be, for example, electrode structures such as comb electrodes, or sensor structures. They are supported by a substrate. This substrate itself may be ceramic, semimetallic or metallic. In particular, the substrate may be a silicon substrate. In addition, it may have a layer of SiO₂ on its surface.

The ceramic precursor polymer is a silicon-containing polymer that is transformed thermally into a silicon-containing ceramic, i.e., ceramicized. This may be carried out at a temperature of ≧850° C. to ≦1200° C., or even of ≧1250° C. to ≦1400° C. Amorphous or crystalline ceramics are obtained, depending on the conditions of ceramization. Depending on the ceramic precursor polymer used, amorphous or crystalline SiC, Si₃N₄, SiO₂, for example, and mixtures or mixed crystals thereof may be obtained.

In conjunction with the present invention, polycarbosilanes are oligomers or polymers which have the carbosilane group -[—C(R1)(R2)-Si(R3)(R4)-]-. Here R1, R2, R3 and R4, independent of each other, are H or alkyl, for example methyl, ethyl or propyl.

Polysilazanes are oligomers or polymers which have the silazane group -[—Si(R5)(R6)-N(R7)-]-. R4, and R6 here, independent of each other, are H or alkyl, for example methyl, ethyl or propyl. Here R7 is H, alkyl, for example methyl, ethyl or propyl, or aryl, for example phenyl.

Polyureasilazanes designate oligomers or polymers which have the ureasilazane group -[—Si(R8)(R9)-N(R10)-C(O)—N(R11)-]-. Here R8, and R9, independent of each other, are H or alkyl, for example methyl, ethyl or propyl. R10 here is H, alkyl, for example methyl, ethyl or propyl, or aryl, for example phenyl.

The polymers that are usable according to the present invention may be used in their pure form, as a mixture with other polymers that are usable according to the present invention, or as a mixture with other compounds. In addition, it is also possible to use polymers which contain components of the types polysiloxane, polycarbosilane, polysilazane and/or polyureasilazane in a polymer molecule. In particular, siloxane-substituted polycarbosilanes may be employed here.

The structures of the ceramic precursor polymer reflect the form of the desired ceramic structures. They have a height of ≦20 μm. Height means here the height perpendicular to the substrate surface. The height may also be ≦16 μm or ≦8 μm. The minimum height of the ceramic precursor structures is a function of the intended use of the ceramic structures, and may be for example ≧0.01 μm, ≧0.1 μm or ≧1 μm. Furthermore, the structures of the ceramic precursor polymer have a width perpendicular to their longitudinal axis of ≦500 μm. The width may also be ≦250 μm or ≦40 μm. The longitudinal axis here means the axis which indicates the longitudinal direction of the structure parallel to the substrate surface. In the case of branched structures such as a comb electrode, to determine the respective longitudinal axes the structure is subdivided into non-overlapping substructures, in order to avoid ambiguities. The dimensions of the structures are the dimensions which are obtained after a possibly inserted drying step to remove a solvent, and after a possibly inserted cross-linking step for the ceramic precursor polymer.

As a result of the dimensions of the structures of the ceramic precursor polymer according to the present invention, during ceramization shrinkage now occurs only in the z direction, i.e., perpendicular to the substrate surface. Hence structures of ceramic precursor polymers may be built up directly on a ceramic, semimetallic or metallic substrate, without these structures being destroyed by shrinkage in the x, y axis directions (i.e., in a direction parallel to the substrate surface) during the later ceramization. Consequently the adhesion of the obtained ceramic structures to the substrate is also preserved, so that the ceramic structures are materially bonded to the substrate.

In one example embodiment, the ceramic precursor polymer also includes cross-linkable functional groups, which are selected from vinyl functional groups and/or allyl functional groups. This may mean that a silicon atom is carrying a vinyl substituent and/or an allyl substituent. Examples of such polymers are depicted below.

-[—CH₂—SiH₂—]_{0.9}-[CH₂—Si(allyl)H—]_{0.1}-

-[—Si(vinyl)(CH₃)—NH—]_{0.20}—[Si(CH₃)H—NH—]_{0.80}-

-[—Si(vinyl)(CH₃)—NH—]_{0.20}-

—[Si(CH₃)H—NH—]_{0.79}-

-[—Si(CH₃)(H/vinyl)-N(Ph)-C(O)—NH—]_{0.01}-

This may also mean, however, that the vinyl and/or allyl groups are bonded to a nitrogen atom of the backbone chain in polysilazanes, or to a carbon atom in the main chain in polycarbosilanes.

The advantage of this is that the vinyl and/or allyl groups may result in cross-linking of the polymer, and thus are able to provide for increased stability of the provided ceramic precursor structures. The cross-linking may be initiated, for example, thermally, radically or photochemically. Thus a radical photoinitiator may be added to the polymer in order to obtain hardening structures under exposure to light.

In another example embodiment, the ceramic precursor polymer includes additives that are selected from the group that includes electrically conductive particles, carbon, amorphous carbon, graphite, fullerenes and/or carbon nanotubes. The additives may be dissolved in the polymer, or may be present as a dispersion. In the case of solid particles, their proportion in the polymer is preferably above the percolation limit. Above this limit particles are in mutual contact, and there is a significant increase in electrical and thermal activity. Other examples of electrically conductive particles, in addition to the indicated carbon modifications, are particles of metal, semimetal or semiconductors. They also include metal nanoparticles. An example of a fullerene is buckminsterfullerene C₆₀.

In this way printed conductors are obtained which may be produced inexpensively and are suitable for use under adverse conditions. The method according to the present invention allows inexpensive large-scale production of these electrically conductive ceramic microstructures. A further advantage is that it is possible to customize the electrical conductivity of the printed conductors over a wide range. The use of the indicated carbon modifications has the additional advantage that silicon-containing ceramics having a higher carbon content than would be possible from the ceramic precursor polymer are accessible.

In another example embodiment, the structures of the ceramic precursor polymer have a width to height ratio ranging from ≧1:1 to ≦25:1. Advantageously, the width to height ratio is around 10:1.

In another example embodiment, the structures of the ceramic precursor polymer are provided using a method selected from the group including hot stamping, screen printing and/or photolithography. These structure-forming methods are especially well suited for producing ceramic precursor structures having the dimensions according to the present invention. In one particular embodiment the structures of the ceramic precursor polymer are provided using photolithography, and the method according to the present invention includes the following steps:
a) providing a mixture containing ≧90 mass % to ≦99.9 mass % of the ceramic precursor polymer, and ≧0.1 mass % to ≦10 mass % of a radical photoinitiator;
b) coating a substrate with the obtained mixture;
c) irradiating the coated substrate surface using ultraviolet light while using a photomask, and washing the substrate surface using an organic solvent;
d) heating the obtained substrate having the structures of the ceramic precursor polymer to a temperature of ≧850° C. to ≦1200° C. at a heating rate of ≧100° C./h to ≦150° C./h;
e) cooling down at a cooling rate of ≧250° C./h to ≦350° C./h.

In step a) the ceramic precursor polymer is mixed with a radical photoinitiator. The ceramic precursor polymer may also be dissolved in a solvent before it is mixed with the photoinitiator, in order to lower its viscosity. An example of a suitable solvent could be cyclohexane. The proportion of the ceramic precursor polymer or its solution in the mixture may be for example ≧90 mass % to ≦99 mass %. The proportion of the polymer or its solution in the mixture with the photoinitiator may also be ≧93 mass % to ≦96 mass %, and the proportion of the photoinitiator ≧4 mass % to ≦7 mass %. Possibilities for the radical photoinitiator are all compounds that release radicals under electromagnetic irradiation.

In step b) a substrate is coated with the mixture. The substrate may be a silicon wafer. In one variant, the silicon wafer may continue to have a silicon dioxide layer with a thickness of ≧0.1 μm to ≦3 μm on the surface that is to be coated. A suitable method for the coating is spin coating.

Step c) relates to the exposure to light using a photomask. The exposure to light activates the radical photoinitiator, and solidification or cross-linking of the ceramic precursor polymer takes place at the irradiated locations. Suitable ultraviolet light may have a wavelength of 254 nm or of 365 nm. The power density of the light on the substrate in this case may range from ≧5 mW/cm² to ≧15 mW/cm². The duration of the exposure may range from ≧15 minutes to ≦30 minutes.

The substrate surface is then washed, in order to remove the polymer from the unexposed places. One suitable organic solvent is cyclohexane. The substrate having the ceramic precursor polymer structures thus obtained is ceramicized in step d) according to the temperature profile, and in step e) is cooled down again.

A further subject matter of the present invention is a silicon-containing ceramic structure obtainable by a method according to the present invention. Electrode structures such as comb electrodes or sensor structures may be named as examples. Advantageously, the silicon-containing ceramic structure is distinguished by the fact that it is materially bonded to the substrate.

In one example embodiment, the silicon-containing ceramic structure according to the present invention has a height of ≦20 μm and a width perpendicular to its longitudinal axis of ≦500 μm. The height may also be ≦16 μm or ≦8 μm and the width may be ≦250 μm or ≦40 μm. The minimum height of the ceramic structures may be for example ≧0.01 μm, ≧0.1 μm or ≧1 μm. It is also possible that the structure may have a width to height ratio ranging from ≧1:1 to ≦25:1. Advantageously, the width to height ratio is from ≧8:1 to ≦12:1.

In another example embodiment of the silicon-containing ceramic structure according to the present invention, the electrical resistance of the structure falls in a range from ≧10⁻³ ohm cm to ≦10¹³ ohm cm.

Another subject matter of the present invention is a sensor that includes a silicon-containing ceramic structure according to the present invention. Examples of such sensors are sensors that analyze the exhaust gas from internal combustion engines. In particular, the sensor may be an exhaust gas temperature sensor, an exhaust gas mass flow sensor or a sensor for nitrogen oxides (NOₓ) in the exhaust gas.

### BRIEF DESCRIPTION OF THE DRAWINGS

FIG. 1 shows a substrate having structures of a ceramic precursor polymer.

FIG. 2 shows the substrate from FIG. 1 after ceramization.

### DETAILED DESCRIPTION

### Example 1

The structures were produced in a clean room under amber light. In this example a 6″ silicon wafer was used, which had a 2 μm thick layer of SiO₂ on the surface to be coated. The ceramic precursor polymer was applied as a mixture with a photoinitiator, using spin coating. The polymer was the allylhydridopolycarbosilane (AHPCS) with the formula -[—CH₂—SiH₂—]_{0.9}-[CH₂—Si(Allyl)H—]_{0.1}-, obtainable from Starfire Systems under the trade name SMP-10. The photoinitiator was 2,2-dimethoxy-1,2-diphenylethane-1-one, obtainable from Ciba Spezialitätenchemie under the trade name Irgacure 651. The polymer to photoinitiator ratio in the mixture was 95 mass % to 5 mass %. To coat the wafer, 6 ml of the mixture were spin coated at 700 rpm for 30 seconds.

### Example 2

The structures were produced in a clean room under amber light. In this example a 6″ silicon wafer was used, which had a 2 μm thick layer of SiO₂ on the surface to be coated. As the coating, a mixture of

polymer: 6 ml Polyramics RD-684
photoinitiator: 0.3 g Irgacure 651
solvent: 0.5 ml butyl acetate
was applied to the silicon wafer by spin coating. Polyramics RD-684 (trade name) was a polysiloxane having allyl and aryl groups on the silicon atoms, obtainable from Starfire Systems. Its chemical formula was —[O—Si(allyl)(aryl)]-. The photoinitiator was 2,2-dimethoxy-1,2-diphenylethane-1-one, obtainable from Ciba Spezialitätenchemie under the trade name Irgacure 651. The polymer to photoinitiator ratio in the mixture was 95 mass % to 5 mass %. To coat the wafer, 6 ml of the mixture were spin coated at 700 rpm for 30 seconds.

Photolithography was carried out using an appropriate mask and by exposure for 30 minutes using a laser with a wavelength of 365 nm and a power density of 12 mW/cm². The exposed wafer was washed with cyclohexane. Ceramization was then performed at a temperature of 1200° C. The heating rate was 133° C./hour. Argon at a flow rate of 10 liters/hour was used as protective gas. The resulting product was cooled from 1200° C. to 300° C. at a cooling rate of 300° C./hour, again using argon at a flow rate of 10 liters/hour as protective gas.

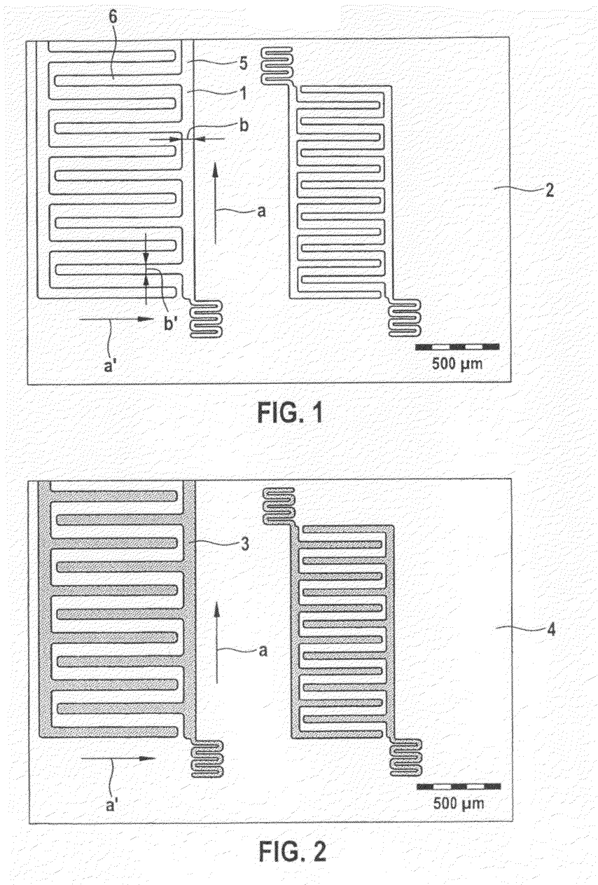

FIG. 1 shows in an optical microscope photograph the structures 1 of the ceramic precursor polymer from Example 1, following the photolithography and washing with cyclohexane. Electrodes in a double comb arrangement are recognizable. Base 5 of one of the combs has the longitudinal axis a. The individual comb elements 6, which are arranged perpendicular to base 5, have the longitudinal axis a′. The width of the structure is indicated perpendicular to the respective longitudinal axis. The width of base 5 is designated as b and the width of the comb elements as b′. The silicon wafer functions here as substrate 2.

FIG. 2 shows, also in an optical microscope photograph, the silicon-containing ceramic structures 3 from the exemplary embodiment which were obtained after ceramization. Compared to the ceramic precursor structures 1 from FIG. 1, no structural change is evident in a direction parallel to the substrate surface. Other than in the height h (this would mean perpendicular to the plane of the picture in this case) there is no shrinkage. The silicon wafer functions here as substrate 4.

1-10. (canceled)

11. A method for producing a silicon-containing ceramic structure, comprising:
providing a structure of a ceramic precursor polymer on the surface of a substrate, the ceramic precursor polymer including at least one of polysiloxanes, polycarbosilanes, polysilazanes and polyureasilazanes; and
ceramicizing the ceramic precursor structure on the substrate, wherein the structure of the ceramic precursor polymer has a height of ≦20 μm and a width of ≦500 μm perpendicular to the longitudinal axis.

12. The method as recited in claim 11, wherein the ceramic precursor polymer further includes at least one cross-linkable functional group, wherein the at least one cross-linkable functional group includes at least one of vinyl functional groups and allyl functional groups.

13. The method as recited in claim 12, wherein the ceramic precursor polymer further includes at least one of the following additives: electrically conductive particles, carbon, amorphous carbon, graphite, fullerenes and carbon nanotubes.

14. The method as recited in claim 12, wherein the structure of the ceramic precursor polymer has a width to height ratio ranging from ≧1:1 to ≦25:1.

15. The method as recited in claim 12, wherein the structure of the ceramic precursor polymer is provided using at least one of hot stamping, screen printing and photolithography.

16. The method as recited in claim 15, wherein the structure of the ceramic precursor polymer is provided using photolithography, including the following steps in sequence:
a) providing a mixture containing ≧90 mass % to ≦99.9 mass % of the ceramic precursor polymer and ≧0.1 mass % to ≦10 mass % of a radical photoinitiator;
b) coating the substrate with the mixture;
c) irradiating the coated substrate surface using ultraviolet light while using a photomask, and subsequently washing the irradiated substrate surface using an organic solvent;
d) heating the substrate having the structure of the ceramic precursor polymer to a temperature of ≧850° C. to ≦1200° C. at a heating rate of ≧100° C./h to ≦150° C./h; and
e) cooling down at a cooling rate of ≧250° C./h to ≦350° C./h.

17. A silicon-containing ceramic structure, comprising:
a substrate; and
a ceramic element formed from a ceramic precursor polymer and located on the surface of the substrate, the ceramic precursor polymer including at least one of polysiloxanes, polycarbosilanes, polysilazanes and polyureasilazanes;
wherein the ceramic element has a height of ≦20 μm and a width of ≦500 perpendicular to the longitudinal axis.

18. The silicon-containing ceramic structure as recited in claim 17, wherein the electrical resistance of the structure lies in a range from ≧10⁻³ ohm cm to ≦10¹³ ohm cm.
